(19) United States
(12) Patent Application Publication
(10) Pub. No.: US 2026/0098884 A1
(43) Pub. Date: Apr. 9, 2026

(54) SYSTEMS AND METHODS FOR MEASURING TIME OR CAPACITANCE

(71) Applicant: Microchip Technology Inc., Chandler, AZ (US)

(72) Inventors: Ezana Haile, Cedar Park, TX (US); Bogdan Bolocan, Eggenstein-Leopoldshafen (DE); Sorin Spanoche, Santa Clara, CA (US)

(73) Assignee: Microchip Technology Inc., Chandler, AZ (US)

(21) Appl. No.: 19/291,404

(22) Filed: Aug. 5, 2025

Related U.S. Application Data
(60) Provisional application No. 63/704,473, filed on Oct. 7, 2024.

(51) Int. Cl. G01R 27/26; G01R 19/25; G01R 19/30; G01R 19/32

(52) U.S. Cl. CPC G01R 27/2605; G01R 19/2509; G01R 19/30; G01R 19/32

(57) ABSTRACT

A system includes a first capacitor, a second capacitor, voltage measurement circuitry to perform differential voltage measurements between the first and second capacitors, and control circuitry to (a) set a ready state with the first capacitor charged and the second discharged, and control the voltage measurement circuitry to perform a pre-event differential voltage measurement between the charged first capacitor and discharged second capacitor, (b) determine an event start, and in response, connect the first capacitor to a low impedance node to effect a partial discharge, and also connect the second capacitor to a low impedance node, and (c) determine an event stop, and in response, control the voltage measurement circuitry to perform post-event differential voltage measurement(s) between the partially discharged first capacitor and the second capacitor, and calculate an event duration between the event start and event stop based on the pre-event differential voltage measurement and post-event differential voltage measurement(s).

### RELATED APPLICATION

This application claims priority to commonly owned U.S. Provisional Patent Application No. 63/704,473 filed Oct. 7, 2024, the entire contents of which are hereby incorporated by reference for all purposes.

### TECHNICAL FIELD

The present disclosure relates to systems and method for measuring time or capacitance, for example based on capacitor discharge.

### BACKGROUND

Certain types of sensors utilize measurement circuitry to measure capacitance or time intervals. For example, LiDAR systems and ultrasound sensor systems typically include or utilize time measurement circuitry to measure “time of flight” of a transmitted and reflected signal, e.g., to detect the distance between a sensor and an object. As another example, a capacitive touch sensor may include or utilize circuitry to measure capacitance between sensor electrodes, e.g., to detect a touch by a person.

One example of such circuitry to measure capacitance or time is “Charge Time Measurement Unit” (CTMU) provided by Microchip Technology Inc. The CTMU is a specialized analog module of a microcontroller that allows for precise measurement of capacitance and very short time intervals by utilizing a controlled current source to charge a capacitor, with the resulting voltage change being proportional to the time elapsed or capacitance value.

However, a conventional CTMU typically achieves time measurement in microseconds of resolution and may involve significant calibration for specified performance across wider operating temperatures. Accordingly, the conventional CTMU may not support certain LiDAR or ultrasound applications, which may require resolution in the range of pico seconds.

There is a need for improved systems, methods, and circuitry for precise measurement of time or capacitance, for example for use with LiDAR, ultrasound, or other “time of flight” based sensor systems, or for use with capacitive touch sensors.

### SUMMARY

Examples of the present disclosure provide systems, methods, and circuitry for precise measurement of time or capacitance. Some examples may be referred to as an enhanced CTMU, or eCTMU.

Some examples of the present disclosure provide improved accuracy and resolution, with reduced jitter and/or high latency, as compared with conventional solutions. Some examples utilize a non-linear charging source (e.g., as compared with a constant current source used in a conventional CTMU). In addition, some examples utilize a precision ADC (e.g., a 16 or 24 bit ADC) and circuitry to detect start and stop times for charge and measurement.

In some examples, a system for measuring time includes (a) a pair of matched capacitors, with a first capacitor maintained in a charged state and a second capacitor maintained in a discharged state during a ready (standby) state, and (b) control logic to detect the start time and stop time of an event defining an event duration (e.g., time-of-flight) to be determined by the system, determine an amount of discharge of the first (charged) capacitor during the event duration, and calculate the event duration based on the determined discharge of the first capacitor. In some examples, the first and second capacitors may be connected to nodes having the same impedance (e.g., wherein both the first and second capacitors are connected to ground during the event, i.e., during the discharge of the first capacitor), to thereby compensate for external impedance effects.

In some examples, the system utilizes a single resistor (or multiple resistors) to discharge the first capacitor during the event duration as detected based on received event start/event stop signals. The control logic may detect event start/event stop signals from an external device (e.g., a sensor), for example using a highspeed control logic, e.g., the Configurable Control Logic or Configurable Logic Cell (CLC) feature provided in a typical microcontroller.

To determine the event duration, upon detection of the event stop signal, the control logic may determine a remaining charge of the first capacitor (having discharged through the resistor during the event duration) by using a high resolution ADC to sample a differential voltage between the first and second capacitors. This implementation relies on ratiometric change in charge stored in the first capacitor. The differential voltage across the capacitors may be sampled before the event start, and at least one time after the event stop. The control logic may calculate the event duration based on the sampled differential voltages before and after the event. In some examples, the control logic samples the differential voltage multiple times after the event in order to determine and compensate for capacitor discharge during ADC sampling.

In some examples, the control logic may calculate the event duration based on the ADC samples (taken before and after the event) using a computational mechanism that compensates for linearity, switching artifacts, finite input impedance of the ADC, and timing offset from the control logic.

One aspect provides a system, comprising a first capacitor, a second capacitor, voltage measurement circuitry to perform differential voltage measurements between the first capacitor and second capacitor, and control circuitry. The control circuitry may be configured to (a) set the system to a ready state with the first capacitor in a charged state and the second capacitor in a discharged state; (b) in the ready state of the system, control the voltage measurement circuitry to perform a pre-event differential voltage measurement between the charged first capacitor and the discharged second capacitor; (c) determine an event start; (d) in response to determining the event start, connect the first capacitor to a first low impedance node to effect a partial time-dependent discharge of the first capacitor, and connect the second capacitor to a second low impedance node; (c) determine an event stop, wherein a time between the event start and the event stop defines an event duration; and (f) in response to determining the event stop, control the voltage measurement circuitry to perform at least one post-event differential voltage measurement between (i) the first capacitor, having partially discharged during the event duration, and (ii) the second capacitor, and calculate the event duration based at least on (i) the pre-event differential voltage measurement and (ii) the at least one post-event differential voltage measurement.

In some examples, a capacitance of the second capacitor is matched with a capacitance of the first capacitor.

In some examples, an impedance of the second low impedance node is matched with an impedance of the first low impedance node.

In some examples, the control circuitry includes circuitry to, in response to determining the event stop: connect the first capacitor to a first high impedance node to inhibit further discharge of the first capacitor, connect the second capacitor to a second high impedance node, and control the voltage measurement circuitry to perform the at least one post-event differential voltage measurement after connecting the first capacitor to the first high impedance node and connecting the second capacitor to the second high impedance node.

In some examples, the system includes a first switch controllable by the control circuitry to selectively connect the first capacitor to the first low impedance node or to the first high impedance node, and a second switch controllable by the control circuitry to selectively connect the second capacitor to the second low impedance node or to the second high impedance node.

In some examples, the voltage measurement circuitry comprises an ADC.

In some examples, the system includes a first resistor connected between the first capacitor and the first low impedance node, and a second resistor connected between the second capacitor and the second low impedance node, the first and second resistors having the same resistance.

In some examples, the first low impedance node and the second low impedance node comprise ground connections.

In some examples, the control circuitry is configured to: perform at least two post-event differential voltage measurements; determine, based on the at least two post-event differential voltage measurements, a sampling-associated discharge of the first capacitor occurring during a respective differential voltage measurement; and use the determined sampling-associated discharge of the first capacitor for calculating the event duration.

Another aspect provide a system, including a first capacitor; a first switch to selectively connect the first capacitor to a first high impedance node or a first low impedance node; a second capacitor; a second switch to selectively connect the second capacitor to a second high impedance node or a second low impedance node; an ADC to perform differential voltage measurements between the first capacitor and second capacitor; and control circuitry. The control circuitry may be configured to (a) maintain the system in a ready state in which the first capacitor is charged, the first switch connects the first capacitor to the first high impedance node, the second capacitor is discharged, and the second switch connects the second capacitor to the second high impedance node; (b) in the ready state of the system, control the ADC to perform a pre-event voltage measurement between the charged first capacitor and discharged second capacitor; (c) determine an event start; (d) in response to determining the event start, control the first switch to connect the first capacitor to the first low impedance node, causing a partial time-dependent discharge of the first capacitor, and control the second switch to connect the second capacitor to the second low impedance node; (c) determine an event stop, wherein a time between the event start and the event stop defines an event duration; and (f) in response to determining the event stop: control the first switch to connect the first capacitor to the first high impedance node; control the second switch to connect the second capacitor to the second high impedance node; control the ADC to perform at least one post-event voltage measurement between (i) the first capacitor, having partially discharged during the event duration, and (ii) the second capacitor, and calculate the event duration based at least on (i) the pre-event voltage measurement and (ii) the at least one post-event voltage measurement.

In some examples, a capacitance of the second capacitor is matched with a capacitance of the first capacitor.

In some examples, an impedance of the second low impedance node is matched with an impedance of the first low impedance node.

In some examples, the system includes a first switch controllable by the control circuitry to selectively connect the first capacitor to the first low impedance node or to the first high impedance node, and a second switch controllable by the control circuitry to selectively connect the second capacitor to the second low impedance node or to the second high impedance node.

Another aspect provides a method, including setting a first capacitor to a charged state; setting a second capacitor to a discharged state; performing a pre-event differential voltage measurement between the first capacitor in the charged state and the second capacitor in the discharged state; determining an event start; in response to determining the event start, connecting the first capacitor to a first low impedance node to effect a partial time-dependent discharge of the first capacitor, and connecting the second capacitor to a second low impedance node; determining an event stop, wherein a time between the event start and the event stop defines an event duration; and in response to determining the event stop, performing at least one post-event differential voltage measurement between (i) the first capacitor, having partially discharged during the event duration, and (ii) the second capacitor, and calculating the event duration based at least on (i) the pre-event voltage measurement and (ii) the at least one post-event voltage measurement.

In some examples, a capacitance of the second capacitor is matched with a capacitance of the first capacitor.

In some examples, an impedance of the second low impedance node is matched with an impedance of the first low impedance node.

In some examples, the method includes, in response to determining the event stop: connecting the first capacitor to a first high impedance node to inhibit further discharge of the first capacitor, connecting the second capacitor to a second high impedance node, and performing the at least one post-event differential voltage measurement after connecting the first capacitor to the first high impedance node and connecting the second capacitor to the second high impedance node.

In some examples, the method includes controlling a first switch to selectively connect the first capacitor to the first low impedance node or to the first high impedance node, and controlling a second switch to selectively connect the second capacitor to the second low impedance node or to the second high impedance node.

In some examples, the method includes using an ADC to perform the pre-event differential voltage measurement and the at least one the post-event differential voltage measurement.

In some examples, the method includes performing at least two post-event differential voltage measurements; determining, based on the at least two post-event differential voltage measurements, a sampling-associated discharge of the first capacitor occurring during a respective differential voltage measurement; and using the determined sampling-associated discharge of the first capacitor for calculating the event duration.

### BRIEF DESCRIPTION OF THE DRAWINGS

Example aspects of the present disclosure are described below in conjunction with the figures, in which:

FIG. 1 shows an example time measurement system for determining a duration of a defined event associated with a sensor system, for example a time-of-flight measurement;

FIG. 2A shows an example system including an example time measurement system for determining a duration of a defined event associated with a sensor system;

FIG. 2B shows an example system including an example capacitive measurement system for measuring a capacitance;

FIG. 3 shows an example timing diagram for various events and functions of an example process for determining a duration of a defined event;

FIG. 4 is a graph showing a differential voltage between first and second capacitors over time throughout a process for measuring a duration of a defined event; and

FIG. 5 shows a representative circuit diagram corresponding with various different phases in an example process for determining an event duration.

It should be understood that the reference number for any illustrated element that appears in multiple different figures has the same meaning across the multiple figures, and the mention or discussion herein of any illustrated element in the context of any particular figure also applies to each other figure, if any, in which that same illustrated element is shown.

### DETAILED DESCRIPTION

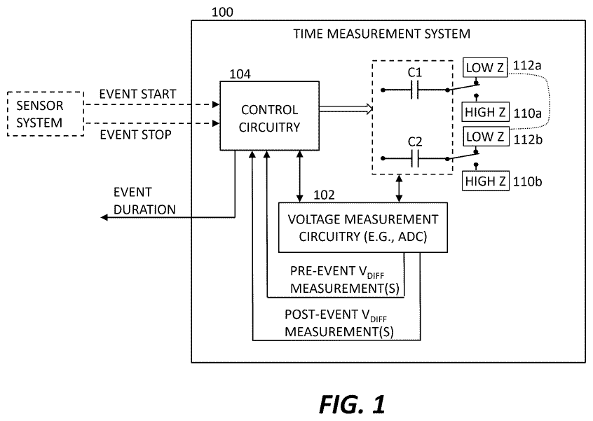

FIG. 1 shows an example time measurement system 100 for determining a duration of a defined event associated with a sensor system S, for example the time-of-flight of a reflected signal in a radar, LiDAR, or ultrasound sensor system. The time measurement system 100 may include a first capacitor C1, a second capacitor C2, voltage measurement circuitry 102 to perform differential voltage measurements between capacitors C1 and C2, and control circuitry 104 to calculate the duration of the defined event, referred to as the “event duration,” based on differential voltage measurements performed by the voltage measurement circuitry 102.

In some examples, capacitors C1 and C2 are matched, for example with a capacitance value within 5% of each other, and in some examples within 1% of each other.

Prior to the event, the control circuitry 104 may set the system 100 to a ready (standby) state with capacitor C1 in a charged state and capacitor C2 in a discharged state. For example, during a charging phase prior to the ready state, control circuitry 104 may charge capacitor C1 fully to a defined charged state (e.g., by connecting capacitor C1 to a power supply) and discharge capacitor C2 fully to a defined discharged state (e.g., by connecting capacitor C1 to ground or other low impedance node). The control circuitry 104 may then connect the charged capacitor C1 and discharged capacitor C2 to high impedance nodes 110a and 110b, respectively, to maintain capacitor C1 in the charged state and capacitor C2 in the discharged state, thus defining the ready (standby) state of the system 100. High impedance nodes 110a and 110b may be implemented as separate high impedance nodes or a common high impedance node to which both capacitors C1 and C2 can be connected.

While in the ready state (and prior to the event), the control circuitry 104 may control the voltage measurement circuitry 102 to perform at least one pre-event differential voltage measurement of the charged capacitor C1 and/or the discharged capacitor C2. In some examples, voltage measurement circuitry 102 comprises an analog-to-digital converter (ADC) circuit, for example a 16-bit or 24-bit ADC.

As used herein, a “differential voltage measurement” may involve (a) a differential measurement (ΔV) between the voltage of capacitor C1 and the voltage of capacitor C2 (i.e., V_{C1}-V_{C2}), for example a differential measurement performed by an ADC circuit, or alternatively (b) a voltage measurement of one capacitor (e.g., V_{C1} of capacitor C1 measured using an ADC circuit) where the voltage of the other capacitor (e.g., V_{C2} of capacitor C2) is known by control circuitry 104.

When the event begins, the control circuitry 104 may determine the start of the event, or the “event start,” at a first time. For example, the control circuitry 104 may receive an event start signal from the sensor system S indicating the start of the event, for example, the transmission of a measurement signal toward an object to be measured. In some examples, the control circuitry 104 may detect event start/event stop signals from an external device (e.g., a sensor), for example using a highspeed control logic, e.g., the Configurable Control Logic or Configurable Logic Cell (CLC) feature provided in a typical microcontroller.

In response to determining the event start, the control circuitry 104 may (a) connect the charged capacitor C1 to a low impedance node 112a, causing capacitor C1 to discharge over time, and (b) connect capacitor C2 to a low impedance node 112b, e.g., having a matched impedance with the low impedance node 112a, to compensate for external impedance effects on the discharging of capacitor C1. In some examples, the low impedance nodes 112a and 112b may be connections to ground. In some examples, the low impedance nodes 112a and 112b may be shorted together (as indicated by the dashed line connecting nodes 112a and 112b), thus providing a floating impedance.

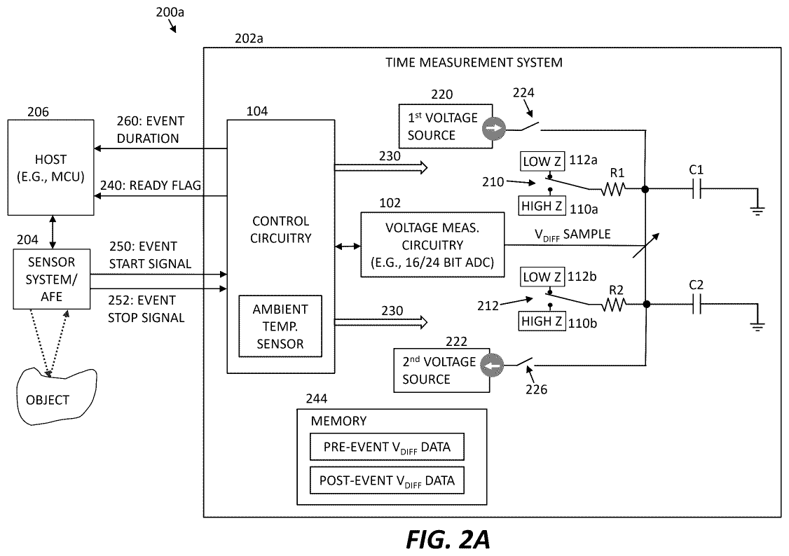

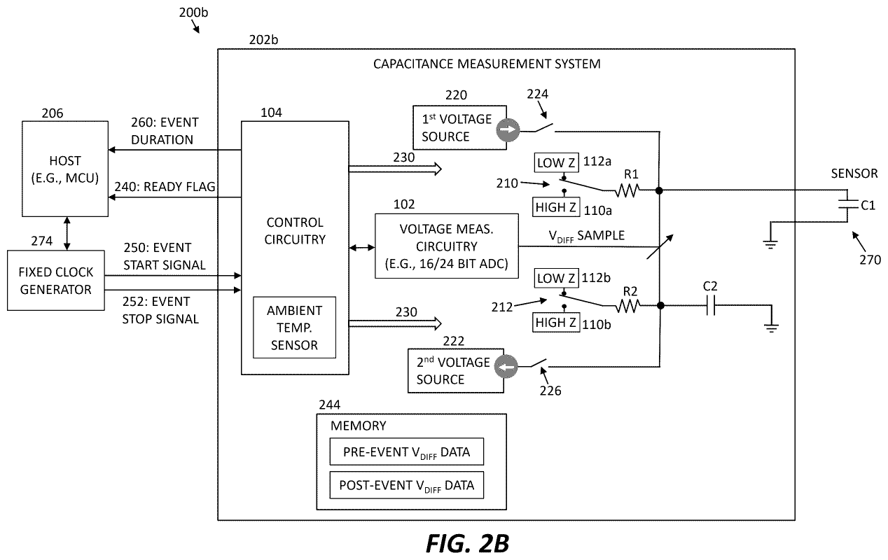

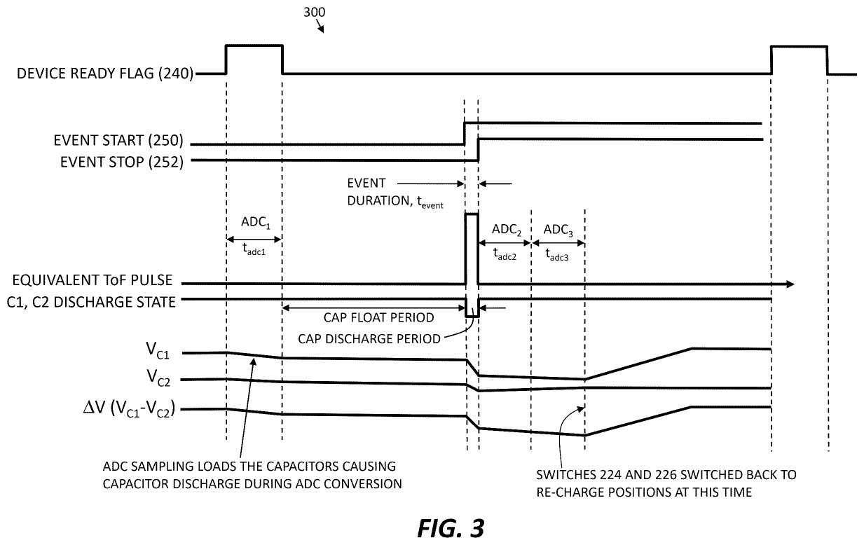

In some examples, e.g., as shown in FIGS. 2A, 2B, and 3 discussed below, a first resistor is connected between capacitor C1 and low impedance node 112a (e.g., ground) to provide a controlled discharge of capacitor C1, and a second resistor having the same resistance as the first resistor is connected between capacitor C2 and low impedance node 112b (e.g., ground).

At some time during the discharging of capacitor C1, the control circuitry 104 determines the end of the event, or the “event stop,” at a second time, wherein the time between the first time and the second time defines the event duration to be measured by the system 100.

In response to determining the event stop, the control circuitry 104 may (a) “fix” the respective charges of capacitors C1 and C2 by connecting capacitors C1 and C2 to respective high impedance nodes, for example high impedance nodes 110a and 110 or other high impedance nodes (or alternatively a common high impedance node), and (b) control the voltage measurement circuitry 102 to perform at least one post-event differential voltage measurement between capacitor C1 (having partially discharged during the event duration between the event start and event stop) and capacitor C2. In some examples, the control circuitry 104 may control the voltage measurement circuitry 102 to perform and compare multiple post-event differential voltage measurements to determine a discharge of capacitor C1 that occurs during each differential voltage measurement, referred to herein as a sampling-associated discharge, which sampling-associated discharge may be used by control circuitry 104 for calculating the event duration.

The control circuitry 104 may then calculate the event duration based at least on (a) the pre-event differential voltage measurement(s) performed during the ready state prior to the event start and (b) the post-event differential voltage measurement(s) performed after the event stop. In some examples, such calculation may account for a sampling-associated discharge of capacitor C1 determined based on the results of multiple post-event differential voltage measurements, as discussed above.

In some examples, control circuitry 104 may include at least one processor and logic instructions embodied in firmware and/or software stored in memory and executable by the at least one processor to perform at least the example functions of system 100 disclosed herein.

FIG. 2A shows an example system 200a including an example time measurement system 202a for determining a duration of a defined event associated with a sensor system 204, for example the time-of-flight of a reflected signal in a radar, LiDAR, or ultrasound sensor system. In some examples, the sensor system 204 may be embodied as an analog front end (AFE) system. As shown, the time measurement system 202a may connect to a host 206 (e.g., a microcontroller or other controller), for example wherein the time measurement system 202a operates as a peripheral provide functionality to the host 206.

The example time measurement system 202a may represent one example implementation of the time measurement system 100 shown in FIG. 1 and discussed above, with like reference numbers referring to like parts. As shown in FIG. 2A, the example time measurement system 202a includes capacitors C1 and C2, voltage measurement circuitry 102, and control circuitry 104, e.g., as discussed above. As discussed above, capacitors C1 and C2 may have a matched capacitance, for example with a capacitance value within 5% of each other, and in some examples within 1% of each other.

The first capacitor C1 is selectively connected between the low impedance node 112a and high impedance node 110a by a first switch 210 controlled by control circuitry 104. A first resistor R1 is connected between capacitor C1 and low impedance node 112a to provide a controlled discharge of capacitor C1. Similarly, the second capacitor C2 is selectively connected between the low impedance node 112b and high impedance node 110b by a second switch 212 controlled by control circuitry 104. As discussed above, in some examples, the low impedance nodes 112a and 112b may be connections to ground, and in other examples, the low impedance nodes 112a and 112b may be shorted together, thus providing a floating impedance.

A second resistor R2 having the same resistance as the first resistor R1 (for example with a resistance within 5% or 1% of each other) is connected between capacitor C2 and low impedance node 112b. In some examples, each of the first resistor R1 and/or the second resistor R2 may include multiple resistors.

In addition, the example time measurement system 202a may include a first voltage source 220 for charging the first capacitor C1 and a second voltage source 222 for discharging the second capacitor C2, e.g., prior to the ready (standby) state of the time measurement system 202a. In some examples, the first voltage source 220 is a defined voltage (e.g., Vcc=3.3V) and the second voltage source 222 is ground.

The first voltage source 220 may be selectively connected to the first capacitor C1 by a switch 224 and the second voltage source 222 may be selectively connected to the second capacitor C2 by a switch 226, wherein switches 224 and 226 are controllable by control circuitry 104.

Switches 210, 212, 224, and 226 discussed above may be respectively controlled by respective switching signals 230 generated by control circuitry 104.

The example system 200a may operate as follows, e.g., to measure the time (duration) of a defined event associated with the sensor system 204, for example the time-of-flight of a reflected signal in a radar, LiDAR, or ultrasound sensor system.

Prior to the event, the control circuitry 104 may set the time measurement system 202a to the ready (standby) state with capacitor C1 in a charged state and capacitor C2 in a discharged state. For example, during a charging phase prior to the ready state, control circuitry 104 may (a) control switch 224 to connect capacitor C1 to the first voltage source 220 (e.g., Vdd) for a time sufficient to fully charge capacitor C1 fully to a defined charged state, and (b) control switch 226 to connect capacitor C2 to the second voltage source 222 to fully discharge capacitor C2 to a defined discharged state.

When capacitor C1 is fully charged, e.g., wherein capacitor C1 is charged to a predefined threshold charge (e.g., Vcc=3.3V), as determined using suitable charge measurement circuitry, the control circuitry 104 may control switches 224 and 226 to disconnect capacitor C1 from the first voltage source 220 and to disconnect capacitor C2 from the second voltage source 222, with switches 210 and 212 controlled to connect capacitors C1 and C2 to the high impedance nodes 110a and 10b, respectively, to thereby maintain capacitor C1 in the charged state and capacitor C2 in the discharged state while awaiting the start of the event, thereby defining the ready (standby) state of the time measurement system 202a. Control circuitry 104 may also send a ready flag 240 to the host 206 indicating the time measurement system 202a is in the ready state (i.e., capacitor Cl is fully charged) for initiating an event by the sensor system 204.

In the ready state of the time measurement system 202a (before an event start signal 250, discussed below), control circuitry may control the voltage measurement circuitry 102 to perform at least one pre-event differential voltage (pre-event VDIFF) measurement between the charged capacitor C1 and discharged capacitor C2, and store the measured pre-event VDIFF data in memory 244.

After the pre-event differential voltage measurement(s), and still in the ready state of the time measurement system 202a, the sensor system 204 may initiate an event (e.g., upon instruction by host 206), for example a radar, LiDAR, or ultrasound measurement of an object involving transmitting a measurement signal (radiation) toward the object and receiving a reflected measurement signal (radiation radiation) from the object. The sensor system 204 sends an event start signal 250 to the time measurement system 202a upon the transmission of the measurement signal, and sends an event stop signal 252 to the time measurement system 202a upon the receipt of the reflected measurement signal, wherein the time between the event start signal 250 and event stop signal 252 defines the event duration, in this case a time-of-flight of the measurement signal transmitted by the sensor system 204, reflected off the object, and received back at the sensor system 204.

The control circuitry 104 receives the event start signal 250 at a first time and in response, controls switches 210 and 212 to switch the connection of capacitors C1 and C2 from the high impedance nodes 110a and 110b to the low impedance nodes (e.g., ground connections) 112a and 112b, respectively. Connecting capacitor C1 to impedance node 112a causes capacitor C1 to begin discharging as a function of time, wherein the rate of discharge is controlled by resistor R1, and connecting capacitor C2 to impedance node 112b (through resistor R2 matched with resistor R1) acts to compensate for external impedance effects on the discharging of capacitor C1.

Subsequently, during the time-dependent discharging of capacitor C1, control circuitry 104 receives the event stop signal 252 at a second time, wherein the time between the first time (receipt of the event start signal 250) and the second time (receipt of the event stop signal 252) defines the event duration to be measured by the time measurement system 202a.

In response to receiving the event stop signal 252, control circuitry 104 controls switches 210 and 212 to switch the connection of capacitors C1 and C2 from the low impedance nodes (e.g., ground connections) 112a and 112b back to the high impedance nodes 110a and 110b, respectively, to thereby fix the respective charges of capacitors C1 and C2. Control circuitry may then control the voltage measurement circuitry 102 to perform at least one post-event differential voltage (post-event VDIFF) measurement between the partially discharged capacitor C1 (having partially discharged during the event duration) and capacitor C2, and store the measured post-event VDIFF data in memory 244.

As mentioned above, in some examples, voltage measurement circuitry 102 may perform multiple post-event VDIFF measurements in succession (e.g., a first post-event VDIFF measurement followed immediately by a second post-event VDIFF measurement) and compare the results to determine the sampling-associated discharge of capacitor C1 that occurs during each VDIFF measurement (e.g., during each pre-event and post-event VDIFF measurement). Control circuitry 104 may then calculate the event duration 260 based at least on (a) the pre-event VDIFF measurement data and post-event VDIFF measurement data, and communicate the calculated event duration 260 to host 206. In some examples, such calculation may account for a sampling-associated discharge of capacitor C1 determined based on the results of multiple post-event VDIFF measurements.

As shown in FIG. 2A, control circuitry 104 may include an integrated ambient temperature sensor 264 to compensate for temperature-related effects when calculating the event duration 260.

FIG. 2B shows an example system 200b including an example capacitive measurement system 202b for measuring an unknown capacitance C1, for example a capacitance generated at a capacitive touch sensor 270. As shown, the capacitive measurement system 202b may connect to a host 206 (e.g., a microcontroller or other controller), for example wherein the capacitive measurement system 202b operates as a peripheral provide functionality to the host 206.

As shown, the example system 200b for measuring an unknown capacitance C1 is fundamentally similar to the example system 200a for measuring an unknown event duration, wherein the capacitive measurement system 202b has a similar architecture as the time measurement system 202a, with like reference numbers used for like parts. As discussed above, in the example time measurement system 202a shown in FIG. 1 (a) a sensor system 204 generates an event start signal 250 and event stop signal 252 defining an unknown event duration (b) the behavior of capacitors C1 and C2 controlled in a known manner are used to calculate the unknown event duration. In contrast, in the example capacitance measurement system 202b shown in FIG. 2, a fixed clock generator 274 may generate a fixed event duration (defined by an event start signal 250 and event stop signal 252), which is used to calculate the unknown capacitance C1, e.g., using similar equations as the event duration calculation.

FIG. 3 shows an example timing diagram 300 for various events and functions involved with an example event duration determination, e.g., as implemented by any of systems 100, 200a, or 200b discussed above. For example, the timing diagram 300 shows:
the status of a device ready flag 240;
the status of an event start signal 250;
the status of an event stop signal 252;
the duration (t_{adc1}) of a pre-event VCAP measurement (ADC₁);
the respective durations (t_{adc2} and t_{adc3}) of a pair of sequential post-event VCAP measurements (ADC₂ and ADC₃);
the voltage (V_{C1}) of the first capacitor C1 and voltage (V_{C2}) of the second capacitor C2; and
the differential voltage ΔV (i.e., V_{C1}-V_{C2}) between capacitor C1 and capacitor C2.

As shown in FIG. 3 (in particular the V_{C1} line), each VCAP measurement (e.g., ADC conversion) loads the capacitors, causing a charged capacitor (e.g., C1) to partially discharge during the measurement (e.g., ADC conversion). As discussed herein, control circuitry 104 may account for this measurement-associated discharge, for example by performing multiple post-event VCAP measurements to determine the discharge resulting from each measurement (e.g., ADC conversion).

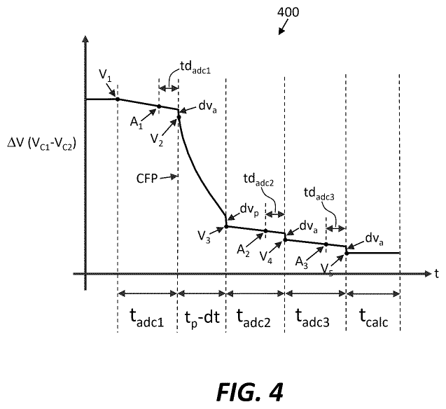

FIG. 4 is a graph 400 showing a differential voltage ΔV, or V_{C1}-V_{C2}, between the first capacitor C1 and second capacitor C2 over time throughout a process for measuring a duration of a defined event, e.g., as implemented by system 100, 200a, or 200b discussed above. FIG. 4 corresponds with FIG. 3, with the exception that the “CAP FLOAT PERIOD” shown in FIG. 3 is omitted from FIG. 4 (in FIG. 4, the event is shown as occurring immediately after the pre-event measurement (t_{adc1}); thus it should be understood such CAP FLOAT PERIOD shown in FIG. 3 would occur at a time corresponding with line “CFP” shown in FIG. 4.

Referring to graph 400 shown in FIG. 4:
tₚ−dt represents the pulse width (tₚ) between the event start signal 250 and event stop signal 252, i.e., the event duration discussed above, minus an offset (dt) of the pulse width, typically caused by start/stop circuit implementation and delay mismatches (e.g., associated with an RS latch);
t_{adc1}, t_{adc2}, and t_{adc3} each represent the ADC conversion time (duration) for a respective ADC measurement (i.e., the pre-event ADC measurement and pair of post-event ADC measurement), at the end of which times the digital output of each ADC conversion (A1, A2, and A3 explained below) is available the ADC is disabled;
A1, A2, and A3 each indicate the voltage output by a respective ADC measurement, each of which voltages corresponds with a point in time during the respective duration (t_{adc1}, t_{adc2}, and t_{adc3}) of each ADC measurement process;
td_{adc1}, td_{adc2}, and td_{adc3} each represent a partial duration at the end of a respective ADC duration t_{adc1}, t_{adc2}, and t_{adc3} after the point of the measured voltages A1, A2, and A3, which partial durations (td_{adc1}, td_{adc2}, and td_{adc3}) indicates a latency of the ADC process, for example resulting from the certain aspects of the conversion process, for example filtering steps (e.g., input analog filtering and output digital filtering, if any);
dvₐ represents a sag in the differential voltage ΔV at the end of each ADC conversion due to disconnection (from sudden ending of the ADC);
dvₚ represents a sag in the differential voltage ΔV due to switching (e.g., charge coupling) upon the event stop signal 252, e.g., controlling switches 210 and 212 to switch capacitors C1 and C1 from connection to low impedance nodes 112a and 112b to high impedance nodes 110a and 110b, respectively; and
V1-V5 represent voltages at the beginning each phase.

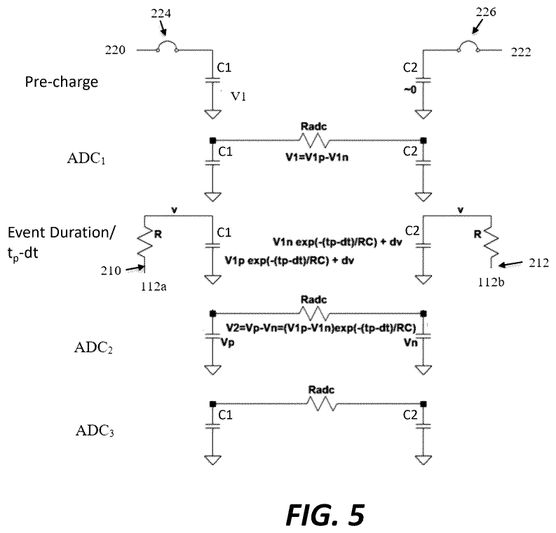

FIG. 5 shows a representative circuit diagram corresponding with each of five different phases in an example process for determining an event duration, including (1) a pre-charge phase, (2) a pre-event differential voltage measurement (ADC₁), (3) the event duration, (4) a first post-event differential voltage measurement (ADC₂), and (5) a second post-event differential voltage measurement (ADC₃). The representative circuit diagrams may be used to derive a calculation of the event duration based on the various parameters discussed above. For example, the control circuitry 104 of example system 100 (FIG. 1) or example system 200a (FIG. 2A) may execute an algorithm based on Equations 1-21 (and optionally Equation 22 and/or 23) copied below to calculate the event duration (tₚ) as a function of the pre-event voltage measurement A1 and two successive post-event voltage measurements A2 and A3. The algorithm may calculate linearized and compensated time measurement results, wherein A1, A2, and A3 are measurement values, and dv_{adc}, dv_{padc}, dt, and τₚ are calibration coefficients.

$${V}_{2} = {V}_{1} {e}^{− {t}_{a} / {τ}_{a}} + {dv}_{a} \qquad ( 1 )$$

$${V}_{3} = {V}_{2} {e}^{− {t}_{p} / {τ}_{p}} + d {v}_{p} \qquad ( 2 )$$

$${V}_{4} = {V}_{3} {e}^{− {t}_{a} / {τ}_{a}} + {dv}_{a} \qquad ( 3 )$$

$${V}_{5} = {V}_{4} {e}^{− {t}_{a} / {τ}_{a}} + {dv}_{a} \qquad ( 4 )$$

$${A}_{1} = A D {C}_{1} \times A D {C}_{R E F} = {V}_{1} {e}^{− \{ {t}_{a} − t {d}_{a} ) / {τ}_{a}} \qquad ( 5 )$$

$${A}_{2} = A D {C}_{2} \times A D {C}_{REF} = {V}_{3} {e}^{− ( {t}_{a} − {td}_{a} ) / {τ}_{a}} \qquad ( 6 )$$

$${A}_{3} = A D {C}_{3} \times A D {C}_{R E F} = {V}_{4} {e}^{− {( {t}_{a} − {td}_{a} )}_{{τ}_{a}}} \qquad ( 7 )$$

$$( 5 ) , ( 6 ) = > {A}_{1} / {A}_{2} = {V}_{1} / {V}_{3} \qquad ( 8 )$$

$$( 6 ) , ( 7 ) = > {A}_{2} / {A}_{3} = {V}_{3} / {V}_{4} \qquad ( 9 )$$

$$( 5 ) = > {V}_{1} = {A}_{1} {e}^{{t}_{a} − {td}_{a} / {τ}_{a}} \qquad ( 10 )$$

$$( 1 ) , ( 10 ) = > {V}_{2} = {A}_{1} {e}^{− t {d}_{a} / {τ}_{a}} + {dv}_{a} \qquad ( 11 )$$

$$( 2 ) , ( 11 ) = > {V}_{3} = {A}_{1} {e}^{- {td}_{a} / {τ}_{a} − {t}_{p} / {τ}_{p}} + {dv}_{a} {e}^{− {t}_{p} / {τ}_{p}} + d {v}_{p} \qquad ( 12 )$$

$$( 8 ) , ( 10 ) , ( 12 ) = > {A}_{1} / {A}_{2} = {V}_{1} / {V}_{3} = {A}_{1} {e}^{{t}_{a} − {td}_{a} / {τ}_{a}} / {A}_{1} {e}^{− {td}_{a} / {τ}_{a} − {t}_{p} / {τ}_{p}} + {dv}_{a} {e}^{− {t}_{p} / {τ}_{p}} + {dv}_{p} \qquad ( 13 )$$

$$\begin{matrix} & ( 13 ) = >\end{matrix} {A}_{1} / {A}_{3} = {e}^{{t}_{a} / {τ}_{a} + {t}_{p} / {τ}_{p}} / 1 + {dv}_{a} {e}^{{td}_{a} / {τ}_{a}} / {A}_{1} + {dv}_{p} {e}^{{td}_{a} / {τ}_{a} + {t}_{p} / {τ}_{p}} / {A}_{1} \qquad ( 13 a )$$

$$\begin{matrix} & Notation {dv}_{adc} = d {v}_{a} {e}^{t {d}_{a} / {τ}_{a}} ; dv + {dv}_{pdac} = d {v}_{p} {e}^{t {d}_{a} / {τ}_{a}}\end{matrix} \qquad ( 14 )$$

$$( 14 ) , ( 13 a ) = > {A}_{1} / {A}_{2} = {e}^{{t}_{a} / {τ}_{a} + {t}_{p} / {τ}_{p}} / 1 + d {v}_{adc} / {A}_{1} + {e}^{{t}_{p} / {τ}_{p}} \times d {v}_{padc} / {A}_{1} \qquad ( 15 )$$

$$( 6 ) = > {V}_{3} = {A}_{2} {e}^{{t}_{a} − {td}_{a} / {τ}_{a}} \qquad ( 16 )$$

$$( 3 ) , ( 16 ) = > {V}_{4} = {A}_{2} {e}^{- {td}_{a} / {τ}_{a}} + {dv}_{a} \qquad ( 17 )$$

$$( 9 ) , ( 16 ) , ( 17 ) = > {A}_{2} / {A}_{3} = {V}_{1} / {V}_{3} = {e}^{{t}_{a} − {td}_{a} / {τ}_{a}} / {e}^{− {td}_{a} / {τ}_{a}} ( 1 + {dv}_{a} {e}^{{td}_{a} / {τ}_{a}} / {A}_{2} ) \qquad ( 18 )$$

$$( 18 ) = > {A}_{2} / {A}_{3} = {e}^{{t}_{a} / {τ}_{a}} / 1 + {dv}_{adc} / {A}_{2} \qquad ( 18 a )$$

$$( 18 a ) = > {e}^{{t}_{a} / {τ}_{a}} = {A}_{2} / {A}_{3} \times ( 1 + {dv}_{adc} / {A}_{2} ) \qquad ( 19 )$$

$$( 15 ) , ( 19 ) = > {A}_{1} / {A}_{2} = {A}_{2} / {A}_{3} \times ( 1 + {dv}_{adc} / {A}_{2} ) \times {e}^{{t}_{p} / {τ}_{p}} / 1 + {dv}_{adc} / {A}_{1} + {e}^{{t}_{p} / {τ}_{p}} \times {dv}_{padc} / {A}_{1} \qquad ( 20 )$$

$$( 20 ) = > {A}_{1} / {A}_{2} + {dv}_{adc} / {A}_{2} + {e}^{{t}_{p} / {τ}_{p}} \times {dv}_{adc} / {A}_{2} = {e}^{{t}_{p} / {τ}_{p}} \times {A}_{2} / {A}_{3} \times ( 1 + {dv}_{adc} / {A}_{2} ) \qquad ( 20 a )$$

$$( 20 a ) = > {A}_{1} + {dv}_{adc} / {A}_{2} = ( {A}_{2} / {A}_{3} + {dv}_{adc} / {A}_{3} ) - {dv}_{padc} / {A}_{2} ) {e}^{{t}_{p} / {τ}_{p}} \qquad ( 20 b )$$

$$( 20 b ) = > {t}_{p} = {τ}_{p} ln ( ( {A}_{1} + {dv}_{adc} ) / {A}_{2} / ( {A}_{2} / {A}_{3} + {dv}_{adc} / {A}_{3} - {dv}_{padc} / {A}_{2} ) ) + dt \qquad ( 21 )$$

Where dt is the extra pulse width offset.
If charge injection is negligible (i.e. dv_{adc} and dv_{padc} are zero) then:

$$( 21 ) = > {t}_{p} = {τ}_{p} ln ( {A}_{1} / {A}_{3} / {A}_{2}^{2} ) + dt \qquad ( 22 )$$

If ADC Input Impedance is infinite and no duty cycle offset, then dt=0 A₂=A₃ and we get the first order model:

$$( 22 ) = > {t}_{p} = {τ}_{p} ln ( {A}_{1} / {A}_{2} ) \qquad ( 23 )$$

In other examples, for example as discussed above regarding system 200b shown in FIG. 2B, a system disclosed herein may be used to determine an unknown capacitance instead of an event duration. As discussed above, rather than using event start and stop signals to control the discharge timing of C1, the control circuitry 104 may use a defined time period (i.e., using predefined start and stop times), and measure the discharge of capacitor C1 during the defined time period to determine capacitance. For example, the control circuitry 104 of example system 200b may execute an algorithm based on the equations copied below to calculate a capacitance C of the capacitor C1 (see FIG. 2B) as a function of the pre-event voltage measurement A1 and two successive post-event voltage measurements A2 and A3.

$$C = \frac{{t}_{p} − d t}{R ln ( ( {A}_{1} + d {v}_{adc} ) / {A}_{2} / ( ( {A}_{2} + d {v}_{adc} ) / {A}_{3} − {dv}_{padc} / {A}_{2} ) )} \qquad ( 24 )$$

$$x = ( {A}_{1} + d {v}_{adc} ) / {A}_{2} / ( ( {A}_{2} + d {v}_{adc} ) / {A}_{3} − {dv}_{padc} / {A}_{2} ) \qquad ( 25 )$$

$${t}_{p} = {τ}_{p} ln ( x ) + d t ≅ {τ}_{p} {\sum }_{k = 0}^{n} {a}_{k} {x}^{k} + d t \qquad ( 26 )$$

$$\begin{matrix}x = ( {A}_{1} + {dv}_{adc} ) / {A}_{2} / ( ( {A}_{2} + {dv}_{adc} ) / {A}_{3} - {dv}_{padc} / {A}_{2} ) \\ ≅ ( {A}_{1} + {dv}_{adc} ) / {A}_{2} / ( ( {A}_{2} + {dv}_{adc} ) ( 1 + da / {A}_{2} ) / {A}_{2} ) - {dv}_{padc} / {A}_{2} )\end{matrix} \qquad ( 27 )$$

$$x ≅ ( {A}_{1} + d {v}_{adc} ) / ( {A}_{2} + d {v}_{adc} ) ( 1 + da / {A}_{2} ) − d {v}_{padc} ) \qquad ( 28 )$$

Although example embodiments have been described above, other variations and embodiments may be made from this disclosure without departing from the spirit and scope of these embodiments.

1. A system, comprising:
a first capacitor;
a second capacitor;
voltage measurement circuitry to perform differential voltage measurements between the first capacitor and second capacitor; and
control circuitry to:
set the system to a ready state with the first capacitor in a charged state and the second capacitor in a discharged state;
in the ready state of the system, control the voltage measurement circuitry to perform a pre-event differential voltage measurement between the first capacitor in the charged state and the second capacitor in the discharged state;
determine an event start;
in response to determining the event start:
connect the first capacitor to a first low impedance node to effect a partial time-dependent discharge of the first capacitor; and
connect the second capacitor to a second low impedance node;
determine an event stop, wherein a time between the event start and the event stop defines an event duration; and
in response to determining the event stop:
control the voltage measurement circuitry to perform at least one post-event differential voltage measurement between (a) the first capacitor, having partially discharged during the event duration, and (b) the second capacitor; and
calculate the event duration based at least on (a) the pre-event differential voltage measurement and (b) the at least one post-event differential voltage measurement.

2. The system of claim 1, wherein a capacitance of the second capacitor is matched with a capacitance of the first capacitor.

3. The system of claim 1, wherein an impedance of the second low impedance node is matched with an impedance of the first low impedance node.

4. The system of claim 1, wherein the control circuitry includes circuitry to, in response to determining the event stop:
connect the first capacitor to a first high impedance node to inhibit a further discharge of the first capacitor;
connect the second capacitor to a second high impedance node; and
control the voltage measurement circuitry to perform the at least one post-event differential voltage measurement after connecting the first capacitor to the first high impedance node and connecting the second capacitor to the second high impedance node.

5. The system of claim 4, comprising:
a first switch controllable by the control circuitry to selectively connect the first capacitor to the first low impedance node or to the first high impedance node; and
a second switch controllable by the control circuitry to selectively connect the second capacitor to the second low impedance node or to the second high impedance node.

6. The system of claim 1, wherein the voltage measurement circuitry comprises an analog-to-digital converter (ADC).

7. The system of claim 1, comprising:
a first resistor connected between the first capacitor and the first low impedance node; and
a second resistor connected between the second capacitor and the second low impedance node, the first and second resistors having the same resistance.

8. The system of claim 1, wherein the first low impedance node and the second low impedance node comprise ground connections.

9. The system of claim 1, wherein the control circuitry is configured to:
perform at least two post-event differential voltage measurements;
determine, based on the at least two post-event differential voltage measurements, a sampling-associated discharge of the first capacitor occurring during a respective differential voltage measurement; and
use the determined sampling-associated discharge of the first capacitor for calculating the event duration.

10. A system, comprising:
a first capacitor;
a first switch to selectively connect the first capacitor to a first high impedance node or a first low impedance node;
a second capacitor;
a second switch to selectively connect the second capacitor to a second high impedance node or a second low impedance node;
an analog-to-digital converter (ADC) to perform differential voltage measurements between the first capacitor and second capacitor;
control circuitry to:
maintain the system in a ready state in which:
the first capacitor is charged;
the first switch connects the first capacitor to the first high impedance node;
the second capacitor is discharged;
the second switch connects the second capacitor to the second high impedance node;
in the ready state of the system, control the ADC to perform a pre-event voltage measurement between the charged first capacitor and discharged second capacitor;
determine an event start;
in response to determining the event start:
control the first switch to connect the first capacitor to the first low impedance node, causing a partial time-dependent discharge of the first capacitor;
control the second switch to connect the second capacitor to the second low impedance node;
determine an event stop, wherein a time between the event start and the event stop defines an event duration;
in response to determining the event stop:
control the first switch to connect the first capacitor to the first high impedance node;
control the second switch to connect the second capacitor to the second high impedance node;
control the ADC to perform at least one post-event voltage measurement between (a) the first capacitor, having partially discharged during the event duration, and (b) the second capacitor; and
calculate the event duration based at least on (a) the pre-event voltage measurement and (b) the at least one post-event voltage measurement.

11. The system of claim 10, wherein a capacitance of the second capacitor is matched with a capacitance of the first capacitor.

12. The system of claim 10, wherein an impedance of the second low impedance node is matched with an impedance of the first low impedance node.

13. The system of claim 10, comprising:
a first switch controllable by the control circuitry to selectively connect the first capacitor to the first low impedance node or to the first high impedance node; and
a second switch controllable by the control circuitry to selectively connect the second capacitor to the second low impedance node or to the second high impedance node.

14. A method, comprising:
setting a first capacitor to a charged state;
setting a second capacitor to a discharged state;
performing a pre-event differential voltage measurement between the first capacitor in the charged state and the second capacitor in the discharged state;
determining an event start;
in response to determining the event start:
connecting the first capacitor to a first low impedance node to effect a partial time-dependent discharge of the first capacitor; and
connecting the second capacitor to a second low impedance node;
determining an event stop, wherein a time between the event start and the event stop defines an event duration; and
in response to determining the event stop:
performing at least one post-event differential voltage measurement between (a) the first capacitor, having partially discharged during the event duration, and (b) the second capacitor; and
calculating the event duration based at least on (a) the pre-event voltage measurement and (b) the at least one post-event voltage measurement.

15. The method of claim 14, wherein a capacitance of the second capacitor is matched with a capacitance of the first capacitor.

16. The method of claim 14, wherein an impedance of the second low impedance node is matched with an impedance of the first low impedance node.

17. The method of claim 14, comprising, in response to determining the event stop:
connecting the first capacitor to a first high impedance node to inhibit further discharge of the first capacitor;
connecting the second capacitor to a second high impedance node; and
performing the at least one post-event differential voltage measurement after connecting the first capacitor to the first high impedance node and connecting the second capacitor to the second high impedance node.

18. The method of claim 17, comprising:
controlling a first switch to selectively connect the first capacitor to the first low impedance node or to the first high impedance node; and
controlling a second switch to selectively connect the second capacitor to the second low impedance node or to the second high impedance node.

19. The method of claim 14, comprising using an analog-to-digital converter (ADC) to perform the pre-event differential voltage measurement and the at least one the post-event differential voltage measurement.

20. The method of claim 14, comprising:
performing at least two post-event differential voltage measurements;
determining, based on the at least two post-event differential voltage measurements, a sampling-associated discharge of the first capacitor occurring during a respective differential voltage measurement; and
using the determined sampling-associated discharge of the first capacitor for calculating the event duration.
